(19) United States
(12) Patent Application Publication
(10) Pub. No.: US 2013/0285196 A1
(43) Pub. Date: Oct. 31, 2013

(54) ESD PROTECTION CIRCUIT PROVIDING MULTIPLE PROTECTION LEVELS

(71) Applicants: MARIANO DISSEGNA, DALLAS, TX (US); GIANLUCA BOSELLI, PLANO, TX (US)

(72) Inventors: MARIANO DISSEGNA, DALLAS, TX (US); GIANLUCA BOSELLI, PLANO, TX (US)

(73) Assignee: TEXAS INSTRUMENTS INCORPORATED, Dallas, TX (US)

(21) Appl. No.: 13/456,951

(22) Filed: Apr. 26, 2012

(51) Int. Cl. H01L 29/06

(52) U.S. Cl. 257/509; 257/E29.019

(57) ABSTRACT

An electrostatic discharge (ESD) protection circuit includes a substrate having a semiconductor surface. A plurality of stacked ESD protection cells are in the semiconductor surface each having a surrounding isolation structure, wherein the ESD protection cells are connected in series by an interconnect and include a first ESD protection cell in series with at least a second ESD protection cell. A plurality of protection pins include a first protection pin across the first ESD protection cell but not across the second ESD protection cell to provide a first voltage rating and a second protection pin across both the first and second ESD protection cell to provide a second voltage rating which is higher than the first voltage rating.

### FIELD

Disclosed embodiments relate to electrostatic discharge (ESD) circuits for protecting multiple pins of integrated circuits.

### BACKGROUND

An integrated circuit (IC) may be subject to damaging ESD events in the manufacturing process, during assembly and testing, or in the ultimate system application. In conventional IC ESD protection schemes, clamp circuits are often used to shunt ESD current to ground during voltage peaks to protect internal circuitry on the IC from ESD-induced damage.

Where multiple ports need to be protected, for instance multiple pins of an IC, a local clamp approach using dedicated separate ESD structures, each with an anode and a cathode, is generally used to protect each pin. What is needed is an ESD protection circuit architecture that requires significantly less space.

### SUMMARY

Disclosed embodiments include electrostatic discharge (ESD) protection circuits comprising a stacked plurality of ESD protection cells in a semiconductor surface each having a surrounding isolation structure. The plurality of ESD protection cells are connected in series by an interconnect, and include a first ESD protection cell in series with at least a second ESD protection cell. The ESD protection circuit includes a plurality of protection pins (by connections to electrode taps including electrode taps within the stack of ESD protection cells) including a first protection pin across the first ESD protection cell but not across the second ESD protection cell to provide a first voltage rating, and a second protection pin across both the first and second ESD protection cell to provide a second voltage rating which is higher than the first voltage rating.

The plurality of electrode taps include overlapping discharge paths which share some of same ESD protection cells for various pin applications. Disclosed embodiments thus mitigate the problem of large chip area needed by conventional high voltage ESD protection arrangements for protecting ICs. In one particular embodiment, the ESD protection circuit is formed on a semiconductor on insulator (SOI) substrate which permits dielectric isolation to be used as the isolation between the ESD protection cells which allows a closer cell spacing as compared to junction isolated cells.

### BRIEF DESCRIPTION OF THE DRAWINGS

Reference will now be made to the accompanying drawings, which are not necessarily drawn to scale, wherein:

FIG. 1A is a cross sectional depiction of an example ESD protection circuit comprising a stacked plurality of isolated ESD protection cells in series which provides multiple protection levels, according to an example embodiment.

FIG. 1B is a cross sectional depiction of an example ESD protection circuit comprising a stacked plurality of isolated ESD protection cells in series which provides multiple protection levels, according to another example embodiment.

FIG. 2A is a cross sectional depiction of a portion of an example ESD protection circuit where the substrate has a first dopant type and the surrounding isolation structure is junction isolation comprising an isolation diffusion of a first dopant type which extends down from the semiconductor surface to provide resistive coupling to the substrate, according to an example embodiment.

FIG. 2B is a cross sectional depiction of a portion of an example ESD protection circuit where the substrate is a SOI substrate which includes a blanket dielectric layer under the semiconductor surface, and wherein the semiconductor surface comprises a plurality of dielectrically isolated semiconductor islands, according to an example embodiment.

FIG. 3A shows a top depiction of an example ESD protection circuit where the plurality of ESD protection cells are arranged in a plurality of rows and a plurality of columns, according to an example embodiment.

FIG. 3B shows a top depiction of an example ESD protection circuit where the plurality of ESD protection cells are arranged in a non-linear configuration, according to another example embodiment.

FIG. 4 illustrates a high level depiction of a construction of an IC into which a disclosed ESD protection circuit may be incorporated to protect a plurality of terminals of the IC, according to an example embodiment.

FIG. 5 shows current-voltage characteristics of an ESD protection cell comprising a stand-alone 10V gate coupled n-channel metal-oxide-semiconductor (GCNMOS) device as compared to the current-voltage characteristics across an entire disclosed ESD protection device that included an array of 12 stacked GCNMOS devices, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

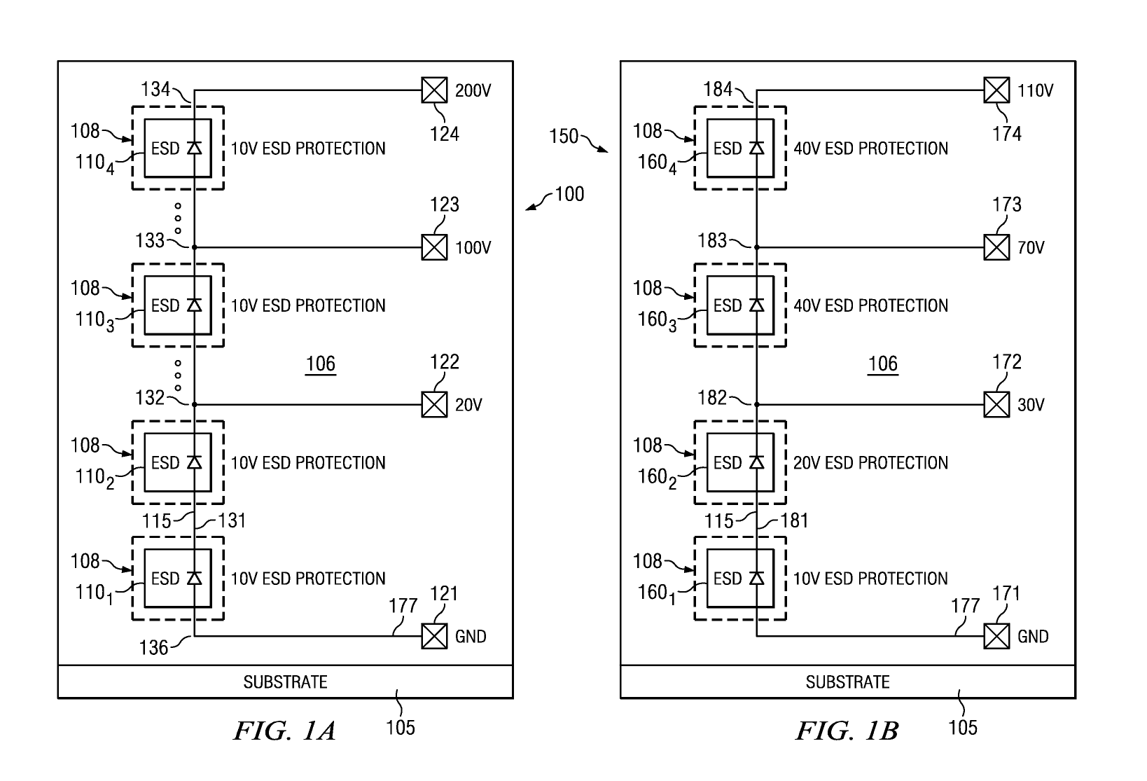

FIG. 1A is a cross sectional depiction of an example ESD protection circuit 100 comprising a stacked plurality of isolated ESD protection cells 110₁, 110₂, 110₃ and 110₄ (110₁-110₄) in series which provides multiple protection levels, according to an example embodiment. Disclosed ESD protection circuits can be embodied as a stand-alone device in one embodiment. Alternatively, disclosed stacked ESD protection circuits can be provided on an IC that includes functional circuitry for carrying out a function, such as a digital (e.g., logic or processor) application or an analog application, with respective electrodes of disclosed stacked ESD protection circuits 100 each providing protection for pins of the IC needing ESD protection, such as described below relative to FIG. 4. Significantly, the masks and processing to fabricate disclosed stacked ESD protection circuits are all generally available in conventional complementary MOS (CMOS) and Bi-CMOS process flows.

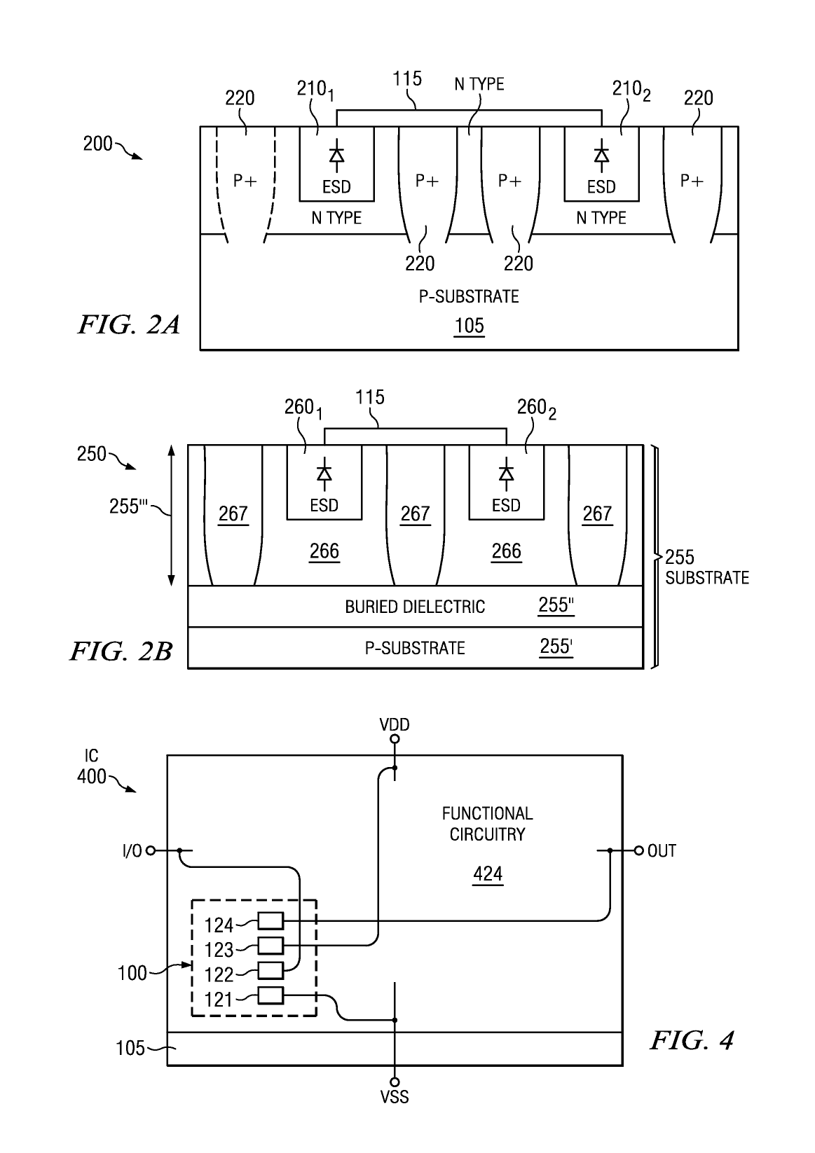

ESD protection circuit 100 comprises a substrate 105 having a semiconductor surface 106, where the plurality of ESD protection cells 110₁-110₄ are formed in the semiconductor surface 106 each having a surrounding isolation structure 108. Although the ESD protection cells 110₁-110₄ are shown with a symbol indicating a reversed biased diode, disclosed ESD protection cells can comprise any type of protection device, including unidirectional devices or bidirectional devices. Example protection devices include those based on silicon controlled rectifiers (SCRs), snapback devices based on npn or pnp bipolar transistors, statically or dynamically triggered, with any type of triggering enhancement circuit, such as capacitors, resistors, MOS field effect transistors (MOSFETs), or zener diodes. Although disclosed ESD protection cells are generally described herein as being unidirectional devices, two disclosed ESD protection cells may be configured in parallel to provide bidirectional protection if desired. The isolation structures 108 can comprise junction isolation (see FIG. 2A described below) or dielectric isolation (see FIG. 2B described below). Although only four (4) ESD protection cells 110₁-110₄ are shown in FIG. 1A, disclosed ESD protection circuits 100 can include as little as two ESD protection cells, or as many as tens of ESD protection cells.

The plurality of ESD protection cells 110₁-110₄ are connected in series by an interconnect 115, typically a metal interconnect, which couples vias that connect to contacts on the semiconductor surface 106 within the ESD protection cells 110₁-110₄ to bond pads for stand-alone embodiments. ESD protection cells 110₁ may be referred to herein as the first ESD protection cell and ESD protection cell 110₂ as the second ESD protection cell.

ESD protection circuit 100 includes a plurality of protection pins 122, 123 and 124 and a ground pin 121 each shown as bond pads which are connected by connector 177 to respective nodes of the stacked ESD protection circuit 100 including protection pin 122 to internal node 132, and protection pin 123 to internal node 133. Protection pin 124 is connected to node 134 which is across all of the ESD protection cells 110₁-110₄. There is no pin shown connected to internal node 131.

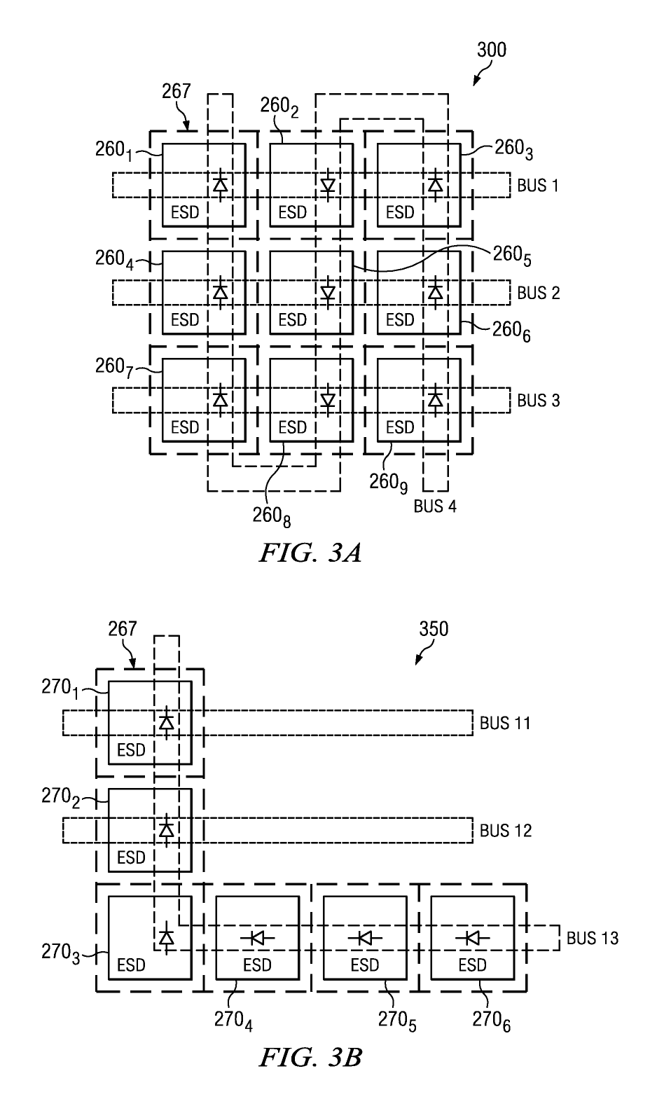

To simplify the description of ESD protection circuit 100 and ESD protection circuits 300 and 350 described below relative to FIGS. 3A and 3B, respectively, the plurality of ESD protection cells 110₁ -110₄ are assumed to be equivalent and all to provide 10 volts of ESD protection. Protection pin 122 being across two (2) series connected ESD protection cells 110₁-110₂ that each provide 10V of ESD protection provides 20V of protection. Protection pin 123 being across ESD protection cells 110₁ -110₂, 110₃ plus 7 additional ESD protection cells represented by the . . . shown in FIG. 1 provides 100V of protection, while protection pin 124 being across ESD protection cells 110₁, 110₂, 110₃ and 110₄, and 7 additional ESD protection cells between ESD protection cells 110₂, 110₃ plus 9 additional ESD protection cells represented by the . . . between ESD protection cells 110₃ and 110₄ provides 200V of protection. Ground pin 121 is connected to node 136.

ESD protection circuit 100 thus provides protection pins 122, 123 and 124 which each provide a plurality of different voltage ratings (20V, 100V and 200V, respectively), with the higher voltage rated pins including the same ESD protection cells as lower voltage rated pins, along with additional ESD protection cells not utilized by the lower voltage rated pins. The respective protection pins thus utilize sharing of some of the discharge paths.

FIG. 1B is a cross sectional depiction of an example ESD protection circuit 150 comprising a stacked plurality of isolated ESD protection cells 160₁, 160₂, 160₃ and 160₄ (160₁-160₄) in series which provides multiple protection levels, according to another example embodiment. In this embodiment ESD protection circuit 150 includes ESD protection cells having two or more different layouts which each provide different voltage ratings. As shown in FIG. 1B, protection pin 172 is coupled to internal node 182 which is across ESD protection cells 160₁ and 160₂ which are assumed to be 10V and 20V rated cells, respectively, to provide 30V of protection, protection pin 173 is coupled to internal node 183 which is across ESD protection cells 160₁, 160₂ and 160₃ which are 10V and 20V and 40V rated cells, respectively, to provided 70V of protection, while protection pin 174 is coupled to node 184 which is across all the ESD protection cells 160₁, 160₂ 160₃ and 160₄ which are 10V, 20V, 40V and 40V rated cells, respectively, to provide 110V of protection. Ground pin 171 is connected to node 186.

As noted above, the isolation structures 108 for disclosed ESD protection circuits can comprise junction isolation and use a bulk substrate (e.g., silicon substrate), or epitaxial substrate (e.g., p− epi on a p+ substrate). For junction isolated embodiments, each ESD protection cell has its own surrounding junction isolation and the size of the isolation region depends on the position of the ESD protection cell in the stack. For example, assuming 10V ESD cells and the stacking of 5 identical ESD cells, the core of every cell can be the same, and every cell receive a different isolation region size. For example, the cell between the 0V (ground) and 10V rails may not need an isolation structure, the cell between 10V and 20V rails can be given a 20V tolerant isolation structure, and the cell between 20V and 30V rails can be given a 30V tolerant isolation structure, and so on. In junction isolated embodiments the distance between adjacent stacked ESD cells cannot be a fixed minimum distance, but instead depends on the isolation voltage rating.

In contrast, in dielectric isolated embodiments enabled by SOI substrates, all ESD protection cells are electrically isolated from one another by a dielectric, so that the distance between adjacent stacked ESD cells can be constant, and be defined by lithography and etch capabilities. Accordingly, a significant advantage of dielectric isolation is there are no spacing limitations relating to stacking of disclosed ESD protection cells, resulting in a minimized chip area for disclosed ESD protection circuits.

FIG. 2A is a cross sectional depiction of a portion of a disclosed ESD protection circuit 200 shown comprising ESD cells 210₁ and 210₂, where the substrate 105 has a first dopant type shown as p-type, and the surrounding isolation structure is junction isolation comprising an isolation diffusion 220 of the same dopant type as the substrate 105 that extends down from the semiconductor surface 106 to provide resistive coupling to the substrate 105, according to an example embodiment. As known in the art, the p-n junctions provided by the junction isolation are reverse biased during IC operation.

FIG. 2B is a cross sectional depiction of a portion of a disclosed stacked ESD protection circuit 250 comprising ESD cells 260₁ and 260₂ where the substrate 255 is a SOI substrate, according to an example embodiment. SOI substrate 255 is shown comprising a p-substrate portion 255′, a buried dielectric (e.g., silicon oxide) portion 255″, and a semiconductor surface portion 255″′ comprising a plurality of semiconductor islands 266. There are vertical dielectric isolation regions 267 surrounding the sidewalls of the semiconductor islands 266. Portion of disclosed stacked ESD protection circuit 250 can be seen to be significantly smaller in area as compared to portion of disclosed ESD protection circuit 200 shown in FIG. 2A.

Whether junction isolated or dielectric isolated, disclosed ESD protection circuits provide an area saving by sharing ESD protection cells of the same ESD protection stack among different pins. Since disclosed ESD protection circuits are formed from a plurality of ESD protection cells, the shape of disclosed ESD protection circuits can easily be adapted to fit into a given space even for irregularly shaped spaces, helping the circuit designer to minimize the area of the overall layout.

For example, FIG. 3A shows a top depiction of an example ESD protection circuit 300 where the plurality of dielectric isolated ESD protection cells 260₁ to 260₉ are arranged in a plurality of rows and a plurality of columns. Metal interconnect lines Bus1-Bus4 are shown which contact the ESD protection cells 260₁ to 260₉ using vias (not shown). ESD protection cells 260₁ to 260₉ are assumed to all be 10V cells.

Bus 4 provides the physical serial connection to all the ESD protection cells (260₁ to 260₉). Bus 1 provides physical connection to ESD protection cells 260₁, 260₆ and 260₇, thereby providing 90V, 40V or 30V of protection, depending on which one the above three cells is connected to Bus 1. Likewise, Bus 2 provides physical connection to ESD protection cells 260₂, 260₅ and 260₈, thereby providing 20V, 50V or 80V of protection, depending on which one of the above three cells is connected to Bus 2. In a similar fashion, Bus 3 provides physical connection to ESD protection cells 260₃, 260₄ and 260₉, thereby providing 10V, 60V or 70V of protection, depending on which one of the above three cells is connected to Bus 3.

FIG. 3B shows a top depiction of an example ESD protection circuit 350 where the plurality of ESD protection cells 270₁ to 270₆ are arranged in an L-shaped configuration. ESD protection cells 270₁ to 270₆ are assumed to all be 10V cells. Bus 13 provides the physical serial connection to all the ESD protection cells. Bus 12 provides physical connection to 270₅, thereby providing 50V of protection Likewise, Bus 11 provides physical connection to 270₆, thereby providing 60V of protection.

FIG. 4 illustrates a high level depiction of a construction of an IC 400 into which a disclosed ESD protection circuit 100 may be incorporated to protect a plurality of terminals of the IC, according to an example embodiment. IC 400 includes functional circuitry 424, which is circuitry that realizes and carries out the desired functionality of IC 400, such as that of a digital IC (e.g., digital signal processor) or analog IC (e.g., amplifier or power converter). The capability of functional circuitry 424 provided by IC 400 may vary, for example ranging from a simple device to a complex device. The specific functionality contained within functional circuitry 424 is not of importance to disclosed embodiments.

IC 400 also includes a number of external terminals, by way of which functional circuitry 424 carries out its function. A few of those external terminals are illustrated in FIG. 4. It is to be understood that the number of terminals and their function can also vary widely. In the example of IC 400 shown in FIG. 4, the terminal shown as I/O operates as a common input and output terminal, by way of which functional circuitry 424 can receive incoming signals and can generate outputs, as well known in the art. IC 400 is shown in FIG. 4 having a dedicated output terminal OUT. Power supply terminal VDD receives a positive power supply voltage in this example, while ground terminal VSS is provided to receive a reference voltage, such as system ground.

IC 400 includes an instance of a disclosed ESD protection circuit 100 at its lower left corner. Protection pin 122 is connected to the I/O pin of functional circuitry 424 to protect I/O circuitry of functional circuit 424, protection pin 123 is connected to VDD to protect circuitry on functional circuit 424 vulnerable to an ESD event applied to VDD, and protection pin 124 is connected to OUT to protect output stage circuitry from an ESD event applied to OUT. Although not shown, another protection pin may be connected between VDD and VSS.

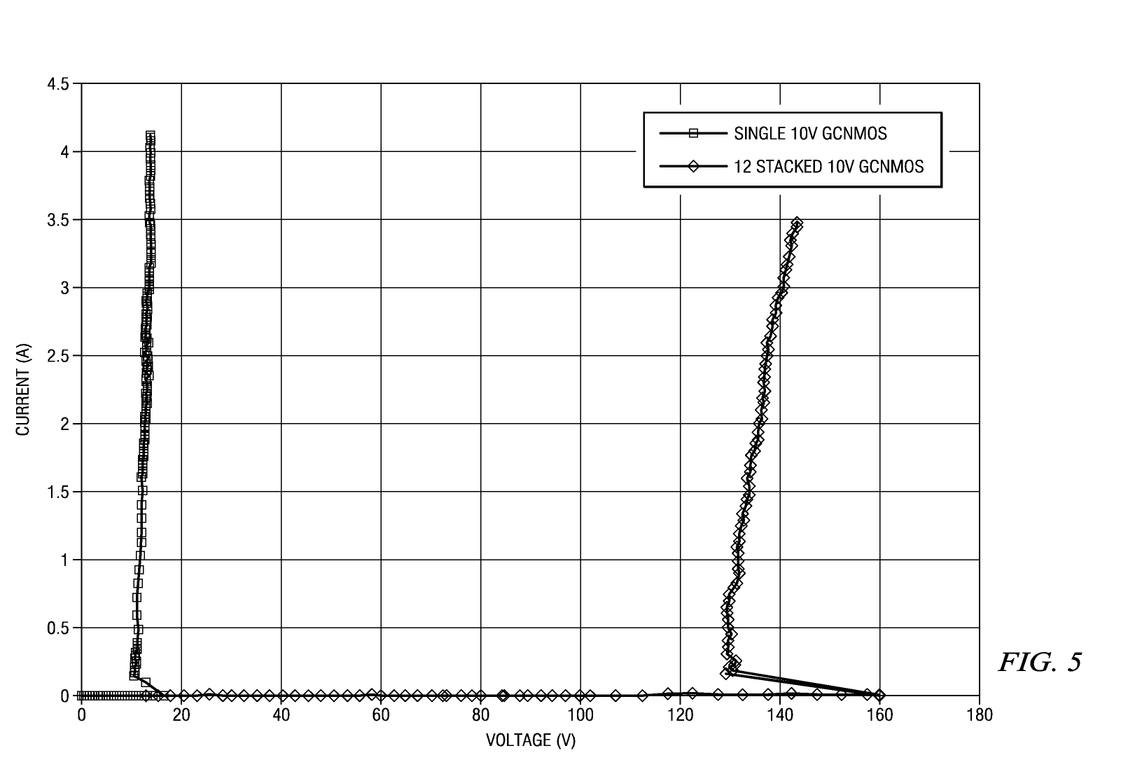

FIG. 5 shows current-voltage characteristics of an ESD protection cell comprising a stand-alone 10V gate coupled GCNMOS device as compared to the current-voltage characteristics across an entire disclosed ESD protection device that includes an array of 12 stacked GCNMOS devices according to an example embodiment. The snapback and holding voltage for the disclosed ESD protection device can be seen to be about 12× that of the stand-alone gated coupled GCNMOS device.

Disclosed embodiments can be integrated into a variety of assembly flows to form a variety of different semiconductor integrated circuit (IC) devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this Disclosure.

We claim:

1. An electrostatic discharge (ESD) protection circuit, comprising:
a substrate having a semiconductor surface;
a plurality of stacked ESD protection cells in said semiconductor surface each having a surrounding isolation structure, wherein said stacked plurality of ESD protection cells are connected in series by an interconnect and include a first ESD protection cell in series with at least a second ESD protection cell, and
a plurality of protection pins including a first protection pin across said first ESD protection cell but not across said second ESD protection cell to provide a first voltage rating and a second protection pin across both said first and said second ESD protection cell to provide a second voltage rating which is higher than said first voltage rating.

2. The ESD protection circuit of claim 1, wherein said semiconductor surface comprises silicon.

3. The ESD protection circuit of claim 1, wherein said stacked plurality of ESD protection cells are unidirectional devices.

4. The ESD protection circuit of claim 1, wherein said substrate has a first dopant type and said surrounding isolation structure is junction isolation comprising an isolation diffusion of said first dopant type which extends down from said semiconductor surface to provide resistive coupling to said substrate.

5. The ESD protection circuit of claim 1, wherein said substrate is a semiconductor on insulator (SOI) substrate which includes a blanket dielectric layer under said semiconductor surface, wherein said semiconductor surface comprises a plurality of dielectrically isolated semiconductor islands, and wherein individual ones of said plurality of stacked ESD protection cells are in respective ones of said dielectrically isolated semiconductor islands.

6. The ESD protection circuit of claim 1, wherein said first ESD protection cell has a different layout and a different voltage rating as compared to said second ESD protection cell.

7. The ESD protection circuit of claim 1, wherein said stacked plurality of ESD protection cells are arranged in a plurality of rows and a plurality of columns.

8. The ESD protection circuit of claim 1, wherein said stacked plurality of ESD protection cells are arranged in a non-linear configuration.

9. An electrostatic discharge (ESD) protection circuit, comprising:
a semiconductor on insulator (SOI) substrate including a blanket dielectric layer under a semiconductor surface that includes a plurality of dielectrically isolated semiconductor islands;
a plurality of stacked ESD protection cells with individual ones of said plurality of stacked ESD protection cells in respective ones of said dielectrically isolated semiconductor islands, wherein said stacked plurality of ESD protection cells are connected in series by an interconnect and include a first ESD protection cell in series with at least a second ESD protection cell, and
a plurality of protection pins including a first protection pin across said first ESD protection cell but not across said second ESD protection cell to provide a first voltage rating and a second protection pin across both said first and said second ESD protection cell to provide a second voltage rating which is higher than said first voltage rating.

10. An integrated circuit (IC), comprising:
a substrate having a semiconductor surface;
functional circuitry on said semiconductor surface configured to realize and carry out a functionality having a plurality of terminals including at least a first terminal and a ground terminal;
an electrostatic discharge (ESD) protection circuit on said semiconductor surface, comprising:
a stacked plurality of ESD protection cells each having a surrounding isolation structure, wherein said stacked plurality of ESD protection cells are connected in series by an interconnect and include a first ESD protection cell in series with at least a second ESD protection cell, and
a plurality of protection pins including a first protection pin across said first ESD protection cell but not across said second ESD protection cell to provide a first voltage rating and a second protection pin across both said first and said second ESD protection cell to provide a second voltage rating which is higher than said first voltage rating, and a ground pin,
wherein said first terminal is coupled to said first protection pin or said second protection pin and wherein said ground terminal is connected to said ground pin.

11. The IC of claim 10, wherein said semiconductor surface comprises silicon.

12. The IC of claim 10, wherein said stacked plurality of ESD protection cells are unidirectional devices.

13. The IC of claim 10, wherein said stacked plurality of ESD protection cells provide bidirectional protection.

14. The IC of claim 10, wherein said substrate has a first dopant type and said surrounding isolation structure is junction isolation comprising an isolation diffusion of said first dopant type which extends down from said semiconductor surface to provide resistive coupling to said substrate.

15. The IC of claim 10, wherein said substrate is a semiconductor on insulator (SOI) substrate which includes a blanket dielectric layer under said semiconductor surface, wherein said semiconductor surface comprises a plurality of dielectrically isolated semiconductor islands, and wherein individual ones of said plurality of stacked ESD protection cells are in respective ones of said dielectrically isolated semiconductor islands.

16. The IC of claim 10, wherein said first ESD protection cell has a different layout and a different voltage rating as compared to said second ESD protection cell.

17. The IC of claim 10, wherein said stacked plurality of ESD protection cells are arranged in a plurality of rows and a plurality of columns.

18. The IC of claim 10, wherein said stacked plurality of ESD protection cells are arranged in a non-linear configuration.
